(19) United States
(12) Patent Application Publication
(10) Pub. No.: US 2026/0164759 A1
(43) Pub. Date: Jun. 11, 2026

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Kohei YAMAUCHI, Hachioji-City (JP); Eiji MOCHIZUKI, Matsumoto-city (JP); Yuji HAYASE, Akishima-city (JP)

(21) Appl. No.: 19/369,289

(22) Filed: Oct. 26, 2025

(30) Foreign Application Priority Data
Dec. 10, 2024 (JP) 2024-215099

(51) Int. Cl. H10D 80/20; H01L 23/31; H01L 23/367; H01L 23/498; H01L 25/00; H01L 25/07

(52) U.S. Cl. CPC H10D 80/251; H10W 40/22; H10W 70/658; H10W 74/114; H10W 74/121; H10W 90/00; H10W 90/701

(57) ABSTRACT

Provided is a semiconductor device, comprising: a circuit board with a wiring; a semiconductor device with a first main electrode and a second main electrode arranged on a first main surface; a bonding portion which bonds the first main electrode and the second main electrode to the wiring; and a resin portion provided in contact with the circuit board and the semiconductor device, in a region where the first main electrode and the second main electrode are not provided, wherein the bonding portion contains a resin; and the resin portion contains resin contains a resin of an identical component to the resin of the bonding portion.

The contents of the following patent application(s) are incorporated herein by reference:
NO. 2024-215099 filed in JP on Dec. 10, 2024.

### BACKGROUND

### 1. Technical Field

The present invention relates to a semiconductor device and a manufacturing method of the semiconductor device.

### 2. Related Art

In Patent Document 1, a circuit board assembly is described to “comprise a circuit board 1, and an electrical component 3 embedded in a cured plastic layer 2” (paragraph 0031). In addition, in the manufacturing method, it is described that “arrange uncured plastic for the plastic layer 2 as a film or a plate onto the circuit board 1 when applying the plastic layer 2 onto the circuit board 1 with an electrical component 3 implemented on one side or both sides. Then cut a window 2A into the plastic at a position of a part 3 to be cooled in advance. In the region of the window 2A, apply solder 5 onto the part 3 to be cooled” paragraph 0039).

Patent Document 1: Japanese Translation Publication of a PCT Route Patent Application No. 2019-536283.

### BRIEF DESCRIPTION OF THE DRAWINGS

FIG. 1 illustrates a perspective view of a semiconductor chip 10 according to the present embodiment.

FIG. 2 illustrates a perspective view of a device 200 according to the present embodiment.

FIG. 3 is a perspective view of a mounting substrate 210 according to the present embodiment.

FIG. 4 illustrates a perspective view of a state in which the semiconductor chip 10, a source electrode 220, a gate electrode 240 and a sub-source electrode 250 are bonded to the mounting substrate 210 according to the present embodiment.

FIG. 5 illustrates a side view of the device 200 according to the present embodiment.

FIG. 6 illustrates a cross-sectional view along an A-A′ line shown in FIG. 2 or FIG. 3.

FIG. 7 illustrates a cross-sectional view of a semiconductor device 800 according to the present embodiment.

FIG. 8 illustrates a flowchart showing one example of a manufacturing method of the semiconductor device 800.

FIG. 9A illustrates preparing a circuit board S1010.

FIG. 9B illustrates applying a bonding material S1020.

FIG. 9C illustrates mounting a device S1030.

FIG. 9D Illustrates Heating S1040.

FIG. 9E illustrates preparing a sinter material S1050.

FIG. 9F illustrates sintering and bonding S1060.

FIG. 10A illustrates formation of a bonding portion 40 in the heating S1040.

FIG. 10B illustrates formation of the bonding portion 40 in the heating S1040.

FIG. 10C illustrates formation of the bonding portion 40 in the heating S1040.

FIG. 11 illustrates a schematic view showing an example inside the bonding portion 40.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to a solution of the invention.

In the present specification, a case where a term such as “same” or “equal” is mentioned may include a case where an error due to a variation in manufacturing or the like is included. The error is, for example, within 10%.

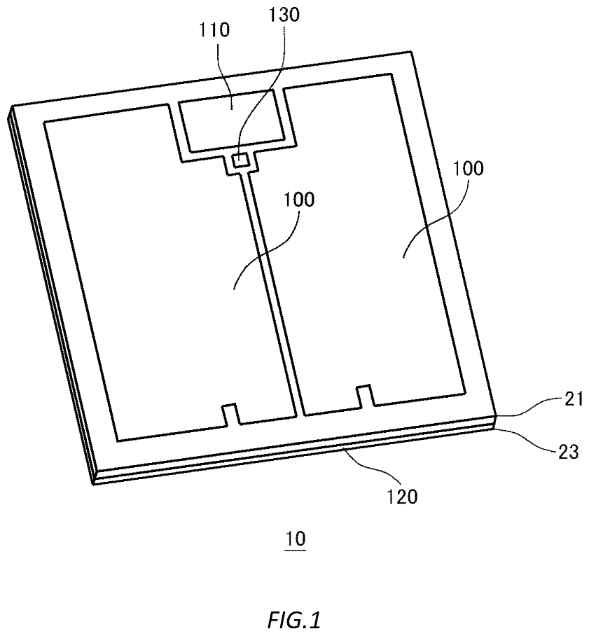

FIG. 1 illustrates a perspective view of a semiconductor chip 10 according to the present embodiment. The semiconductor chip 10 is a switching device such as a MOSFET (Metal Oxide Semiconductor Field Effect Transistor) or the like. The semiconductor chip 10 may be a vertical-type switching device. In the present example, the semiconductor chip 10 is a vertical-type MOSFET. The semiconductor chip 10 may be a Si semiconductor device such as a Si-MOSFET, or a SiC semiconductor device such as a SiC-MOSFET that is switchable faster, or a device using a wide-gap semiconductor such as GaN, diamond, gallium nitride material, gallium oxide material, AlN, AlGaN, or ZnO. Alternatively, the semiconductor chip 10 may be a semiconductor switching device such as an IGBT (Insulated Gate Bipolar Transistor), or a SiC-IGBT. In addition, the semiconductor chip 10 may be a HEMT (High Electron Mobility Transistor).

The semiconductor chip 10 has an upper surface 21 and a lower surface 23. The upper surface 21 and the lower surface 23 are two main surfaces of the semiconductor chip 10. The semiconductor chip 10 has a source pad 100 arranged on the upper surface 21, a gate pad 110, and a drain pad 120 arranged on the lower surface 23. The source pad 100 is an example of a first main pad, and the drain pad 120 is an example of a second main pad. For example, when the semiconductor chip 10 is an IGBT, an emitter pad is provided instead of the source pad 100 as a first main pad, and a collector pad is provided instead of the drain pad 120 as a second main pad. Each pad may be formed of a metal such as aluminum. By applying a certain gate voltage on the gate pad 110, a main current flows between the source pad 100 and the drain pad 120. The semiconductor chip 10 may further have a sense pad 130 on the upper surface 21.

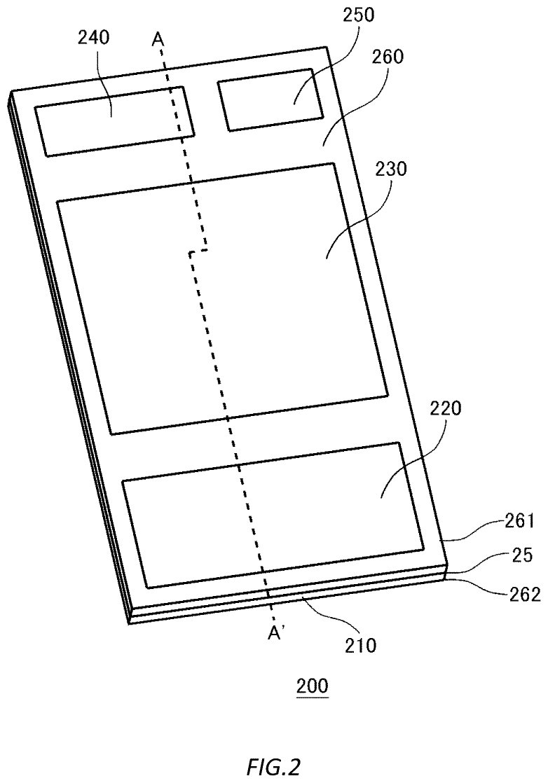

FIG. 2 illustrates a perspective view of a device 200 according to the present embodiment. A semiconductor module that uses a switching device such as the semiconductor chip 10 shown in FIG. 1 generally employs a structure where a pad (for example, drain pad 120) provided on one surface (for example, the lower surface 23) of the switching device is bonded to a wiring pattern on the substrate, and each pad (for example, the source pad 100, the gate pad 110 and the sense pad 130) on the other surface (for example, the upper surface 21) is electrically connected to another wiring pattern by wire bonding. Such a semiconductor module is implemented as an integral module by encapsulating, using a resin, a substrate on which the switching element is mounted, each bonding wire, and each metal plate connected to a positive terminal, a negative terminal, and an output terminal.

On the other hand, the device 200 has a structure where each electrode electrically connected to each pad of the semiconductor chip 10 is exposed on one surface of the board-shaped device 200. In the present embodiment, the device 200 includes a mounting substrate 210, a source electrode 220, a drain electrode 230, a gate electrode 240, a sub-source electrode 250, and a sealing portion 260.

The mounting substrate 210 has the semiconductor chip 10 mounted on a loading face 25 (the upper surface in the drawing). The source electrode 220 is electrically connected to the source pad 100 of the semiconductor chip 10. The drain electrode 230 is electrically connected to the drain pad 120 of the semiconductor chip 10. The gate electrode 240 is electrically connected to the gate pad 110 of the semiconductor chip 10. The sub-source electrode 250 is electrically connected to the source pad 100 of the semiconductor chip 10.

The source electrode 220 is an example of a first main electrode, and the drain electrode 230 is an example of a second main electrode. The first main electrode and the second main electrode are electrodes where a main current of the semiconductor chip 10 flows. The main current refers to a current with the largest amplitude among currents flowing through the semiconductor chip 10. The main current is, for example, a current flowing between the emitter and collector in an IGBT, or a current flowing between the source and the drain in a MOSFET. For example, when the semiconductor chip 10 is an IGBT, an emitter electrode is provided instead of the source electrode 220 as a first main electrode, and a collector electrode is provided instead of the drain electrode 230 as a second main electrode. In addition, the sub-source electrode 250 is an example of the sub-electrode. When the semiconductor chip 10 is an IGBT, a sub-emitter electrode is provided instead of the sub-source electrode 250 as a sub-electrode.

A surface opposite to the mounting substrate 210 side of the device 200 is referred to as a first main surface 261. The first main surface 261 is a surface of the sealing portion 260. In addition, a surface opposite to the sealing portion 260 side of the device 200 is referred to as a second main surface 262. The second main surface 262 is also a main surface on a side opposite to the loading face 25 on the mounting substrate 210. The source electrode 220, the drain electrode 230, the gate electrode 240 and the sub-source electrode 250 are arranged on the first main surface 261. The sealing portion 260 exposes at least a portion of the source electrode 220, the drain electrode 230, the gate electrode 240 and the sub-source electrode 250 while covering the semiconductor chip 10 and the loading face 25. The sealing portion 260 may be a molding material. Note that the sealing portion 260 may not be provided.

Instead of modularizing a switching device such as the semiconductor chip 10 as described above, by bonding each electrode of the first main surface 261 of the device 200 by using the device 200 in the present embodiment to the wiring pattern on the substrate, all necessary electrodes on the semiconductor chip 10 can be electrically connected to the wiring on the substrate without wire bonding. Therefore, as will be described later, it can be directly bonded to a printed circuit board or the like, making it possible to thinner the thickness of the module and significantly reduce inductance and thermal resistance.

Note that the device 200 may further have an electrode electrically connected to the sense pad 130 to the first main surface 261. In addition, either of the source electrode 220 and the sub-source electrode 250 is electrically connected to the source pad 100 of the semiconductor chip 10, but the source electrode 220 has a large area and is used to pass a large current (main current), and the sub-source electrode 250 is used to control the semiconductor chip 10 in a pair with the gate electrode 240. In another form, the device 200 may not include a sub-source electrode 250, and in this case, the source electrode 220 is used to control the semiconductor chip 10.

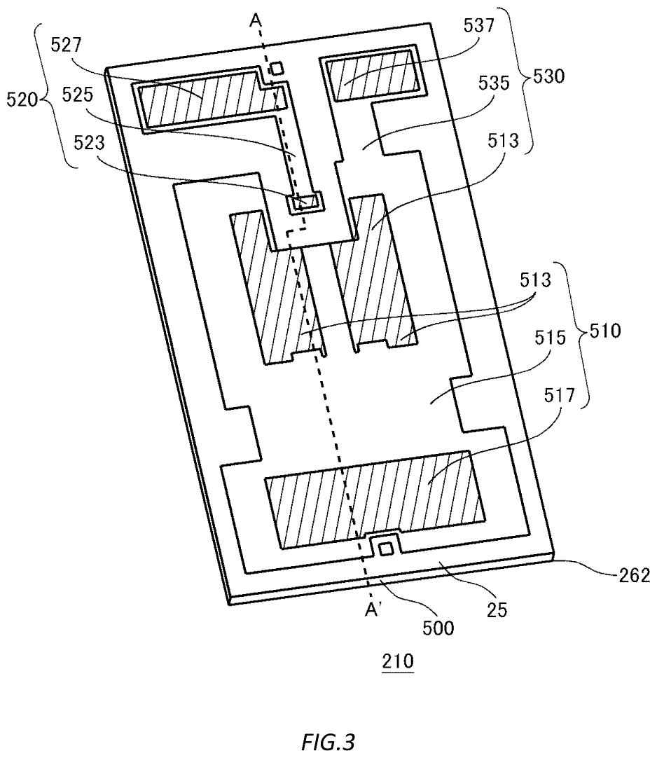

FIG. 3 illustrates a perspective view of the mounting substrate 210 according to the present embodiment. The mounting substrate 210 has an insulating substrate 500, a source electrode wiring 510, a gate electrode wiring 520 and a sub-source electrode wiring 530.

The insulating substrate 500 may be a substrate made of Si, silicon nitride, or aluminum nitride, or other ceramic materials. Wiring patterns of the source electrode wiring 510, the gate electrode wiring 520 and the sub-source electrode wiring 530 are provided on the loading face 25 that is a surface of the insulating substrate 500.

The source electrode wiring 510 is formed from a conductive metal film or metal board such as copper. The source electrode wiring 510 includes a source pad contact 513, a wiring 515 and a source electrode contact 517. The source pad contact 513 is an area connected to the source pad 100 of the semiconductor chip 10. The wiring 515 electrically connects the source pad contact 513 and the source electrode contact 517 in between. The source electrode contact 517 is an area connected to the source electrode 220. In FIG. 3, the source pad contact 513 and the source electrode contact 517 are hatched. The source electrode wiring 510 is an example of the first main electrode wiring. For example, when the semiconductor chip 10 is an IGBT, the first main electrode wiring becomes an emitter electrode wiring instead of the source electrode wiring 510.

Similar to the source electrode wiring 510, the gate electrode wiring 520 is formed from a conductive metal film or metal board such as copper. The gate electrode wiring 520 includes a gate pad contact 523, a wiring 525 and a gate electrode contact 527. The gate pad contact 523 is an area connected to the gate pad 110 of the semiconductor chip 10. The wiring 525 electrically connects the gate pad contact 523 and the gate electrode contact 527 in between. The gate electrode contact 527 is an area connected to the gate electrode 240. In FIG. 3, the gate pad contact 523 and the gate electrode contact 527 are hatched.

Similar to the source electrode wiring 510, the sub-source electrode wiring 530 is formed from a conductive metal film or a metal board such as copper. The sub-source electrode wiring 530 includes a source pad contact 513, a wiring 535 and a sub-source electrode contact 537. The source pad contact 513 is shared with the source electrode wiring 510. The sub-source electrode wiring 530 may use a portion of the source pad contact 513 used by the source electrode wiring 510. The wiring 535 electrically connects the source pad contact 513 and the sub-source electrode contact 537 in between. A wiring width of the wiring 535 may be smaller than that of the wiring 515. The sub-source electrode contact 537 is an area connected to the sub-source electrode 250. In FIG. 3, the sub-source electrode contact 537 is hatched. The sub-source electrode wiring 530 is an example of the sub-electrode wiring. For example, when the semiconductor chip 10 is an IGBT, the sub-electrode wiring becomes the wiring of the sub-emitter electrode instead of the sub-source electrode wiring 530.

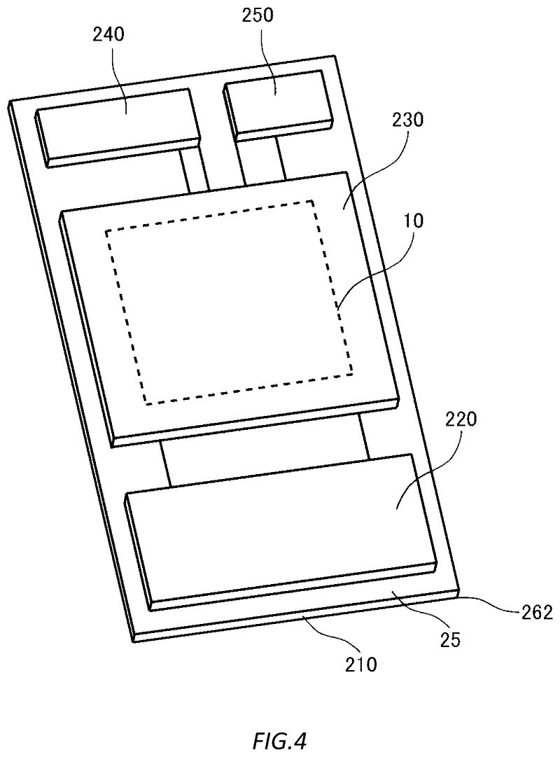

FIG. 4 illustrates a perspective view in a state where the semiconductor chip 10, the source electrode 220, the gate electrode 240 and the sub-source electrode 250 are bonded to the mounting substrate 210 according to the present embodiment. In the present example, the drain electrode 230 is bonded to the drain pad 120 of the semiconductor chip 10. The drain electrode 230 is also a conductive plate-shaped member such as a copper plate. In FIG. 4, the position of the semiconductor chip 10 located below the drain electrode 230 is shown by dotted lines.

The drain electrode 230 may be bonded to the drain pad 120 by using silver sinter bonding. The bonding may be by direct metal-to-metal bonding. The direct bonding is a method of directly bonding the drain pad 120 and the drain electrode 230, and the metal types may be gold-to-gold or copper-to-copper. In addition to the above, the bonding may be performed via a solder material or a gold pillar. In addition, a plurality of bumps arranged regularly or irregularly on the drain electrode 230 may be bonded to the drain pad 120 of the semiconductor chip 10. In this manner, the drain electrode 230 is electrically connected to the drain pad 120. Note that the drain electrode 230 may not be provided. In that case, the drain pad 120 may be directly exposed on the first main surface 261 of the device 200. In the present specification, the drain electrode 230 also includes the drain pad 120 in that case.

The semiconductor chip 10 is bonded to the loading face 25 of the mounting substrate 210 with the upper surface 21 of the semiconductor chip 10 in FIG. 1 facing downward. In this manner, the source pad 100 of the semiconductor chip 10 is bonded to the source pad contact 513 of the source electrode wiring 510 and the sub-source electrode wiring 530, and the gate pad 110 of the semiconductor chip 10 is bonded to the gate pad contact 523 of the gate electrode wiring 520. These bonding methods may be similar to the bonding method of the drain electrode 230 to the drain pad 120.

In FIG. 4, the mounting substrate 210 according to the present embodiment is bonded to the source electrode 220, the gate electrode 240 and the sub-source electrode 250. The source electrode 220 is bonded to the source electrode contact 517 of the source electrode wiring 510. The gate electrode 240 is bonded to the gate electrode contact 527 of the gate electrode wiring 520. The sub-source electrode 250 is bonded to the sub-source electrode contact 537 of the sub-source electrode wiring 530. These bonding methods may be similar to the bonding method of the drain electrode 230 to the drain pad 120.

In this manner, the source electrode 220 is electrically connected to the source pad 100, and the gate electrode 240 is electrically connected to the gate pad 110. A main current flows between the drain electrode 230 and the source electrode 220, and a control signal of the semiconductor chip 10 is input to the gate electrode 240.

As shown in FIG. 4, the source electrode 220 is arranged at a position not overlapping the semiconductor chip 10. The same applies to the gate electrode 240 and the sub-source electrode 250. In this manner, the distance between the semiconductor chip 10 and each electrode can be ensured, and the influence of heat generation from the semiconductor chip 10 can be suppressed.

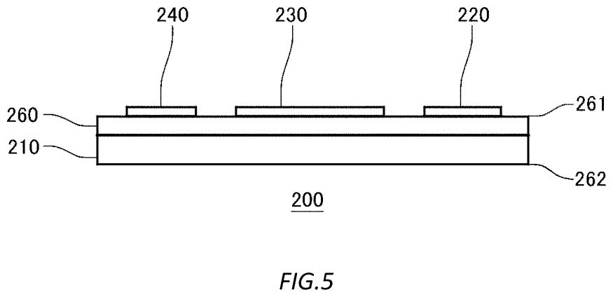

FIG. 5 illustrates a side view of the device 200 according to the present embodiment. As described above, a sealing portion 260 is provided above the mounting substrate 210. A portion of the source electrode 220, the drain electrode 230 and the gate electrode 240 is covered by the sealing portion 260, and a portion is exposed above the first main surface 261 of the sealing portion 260. In other words, in a plane parallel to the first main surface 261, at least a portion of the space between each electrode is not filled with the sealing portion 260. The same may apply to the sub-source electrode 250.

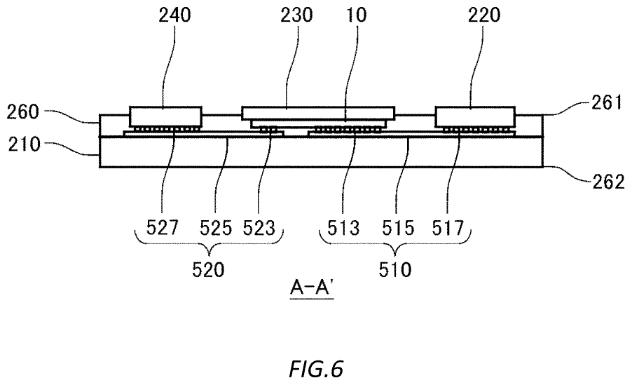

FIG. 6 is a cross-sectional view along an A-A′ line shown in FIG. 2 or FIG. 3. The cross section along the A-A′ line is a cross section across the semiconductor chip 10, the source electrode 220, the drain electrode 230, the gate electrode 240, the source electrode wiring 510 and the gate electrode wiring 520. In the cross section, the semiconductor chip 10 is connected to the drain electrode 230, the source pad contact 513 and the gate pad contact 523. In addition, the source electrode 220 is connected to the source electrode contact 517, and the gate electrode 240 is connected to the gate electrode contact 527. These connection points may all be covered by the sealing portion 260. In addition, no electrode is provided in the second main surface 262, and the second main surface 262 is isolated.

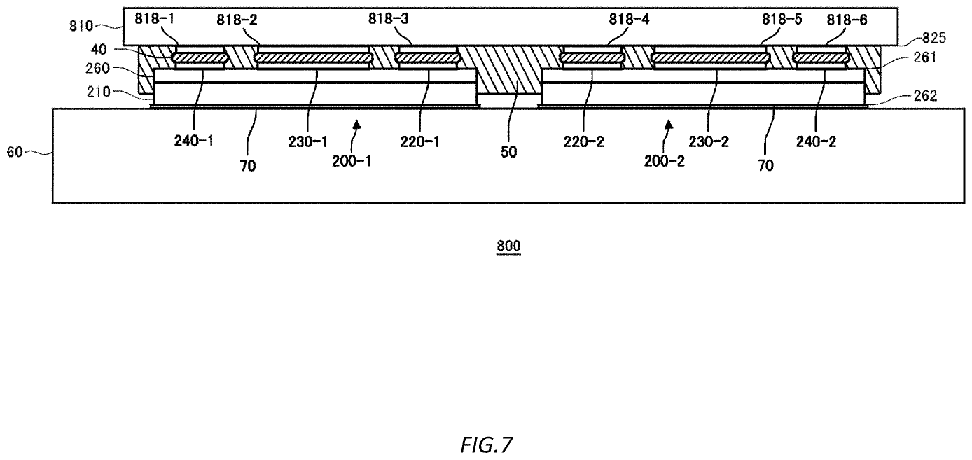

FIG. 7 illustrates a cross-sectional view of the semiconductor device 800 according to the present embodiment. The semiconductor device 800 includes a device 200, a circuit board 810, a bonding portion 40 and a resin portion 50. The semiconductor device 800 may further include a cooler 60 and a sintering portion 70.

The device 200 is the device 200 described in FIG. 1 to FIG. 6. Note that in FIG. 7, an illustration of the inside configuration of the device 200 described in FIG. 6 is omitted. The semiconductor device 800 may include one device 200, or may include a plurality of devices 200. In the present example, the semiconductor device 800 includes a device 200-1 and a device 200-2. The device 200-2 is arranged in the plane parallel to the device mounting surface of the circuit board 810, with the device 200-1 rotated by 180 degrees. In FIG. 7, the orientation in which each electrode of the device 200-2 is arranged (for example, a direction from the source electrode 220 to the gate electrode 240) is 180 degrees different from the orientation in which each electrode of the device 200-1 is arranged.

The device 200 may be a power device (power semiconductor) that controls and converts high voltage and high current. The device 200 may not be a semiconductor device used in a logic semiconductor for performing information processing or the like, or a MEMS (Micro Electro Mechanical System). As an example, the rated current of the device 200 may be 1 A or more. As an example, the semiconductor device 800 is used as an inverter for vehicles.

The circuit board 810 has wirings 818-1 to 818-6. At least a portion of these wires is provided inside the circuit board 810 and transmits a current, signal, or the like to the device 200. In FIG. 7, among the two main surfaces of the circuit board 810, the wirings 818-1 to 818-6 exposed on a surface 825, which is the surface on the device 200 side, are illustrated. The circuit board 810 may be a printed circuit board. In addition, in the present specification, the reference numeral of the configuration of device 200-1 may be prefixed with -1, and the reference numeral of the configuration of device 200-2 may be prefixed with -2. For example, the source electrode 220 of the device 200-1 may be shown as a source electrode 220-1.

The bonding portion 40 bonds the source electrode 220-1 to the wiring 818-3, and bonds the drain electrode 230-1 to the wiring 818-2, respectively.

In addition, the bonding portion 40 bonds the source electrode 220-2 to the wiring 818-4, and bonds the drain electrode 230-2 to the wiring 818-5, respectively. The bonding portion 40 may bond another electrode, such as the gate electrode 240-1 or the sub-source electrode 250-1, to the wiring 818-1. In addition, the bonding portion 40 may bond another electrode, such as the gate electrode 240-2 or the sub-source electrode 250-2, to the wiring 818-6. The bonding portion 40 electrically connects each electrode to each of the wirings 818-1 to 818-6. The device 200-1 and the device 200-2 may be connected in parallel. That is, the source electrode 220-1 and the source electrode 220-2 may be connected by the wiring 818-3 and the wiring 818-4. In addition, the drain electrode 230-1 and the drain electrode 230-2 may be connected by the wiring 818-2 and the wiring 818-5. In another example, the device 200-1 and the device 200-2 may be connected in series, forming an arm. That is, the source electrode 220-1 and the drain electrode 230-2 may be connected by the wiring 818-2 and the wiring 818-5. In FIG. 7, the bonding portion 40 is shown with fine hatching. The bonding portion 40 may be soldered.

The resin portion 50 is provided in contact with the circuit board 810 and the power device 200 in a region where the source electrode 220 and the drain electrode 230 are not provided. The resin portion 50 may be filled in a space between the circuit board 810 and the power device 200. In the present example, the resin portion 50 is provided between the first main surface 261 of the device 200 and the surface 825 of the circuit board 810, between the devices 200, and on a portion of the side surface of the device 200. In FIG. 7, the resin portion 50 is shown with rough hatching. The resin portion 50 may be a thermo-curing resin or an epoxy resin.

In the present example, the bonding portion 40 contains resin. When the bonding portion 40 is soldered, voids may be formed in the solder, and the voids may contain resin. The bonding portion 40 is a portion responsible for electrically connecting the electrodes to the wirings 818-1 to 818-6, and the portion may contain resin inside. The resin contained in the bonding portion 40 can be identified by transmitting an X-ray through the inside of the solder during or after solder mounting. The resin contained in the bonding portion 40 in an internal region away from the end face of the bonding portion 40 may be referred to as the resin contained in the bonding portion 40. The internal region may be 1 mm or more away, or 2 mm or more away, or 5 mm or more away from the end face of the bonding portion 40.

In the present example, the resin portion 50 contains a resin of an identical component to the resin of the bonding portion 40. In other words, the resin of the identical component to the resin of the resin portion 50 is contained in the bonding portion 40. The resin may be distributed throughout the entire resin portion 50. The main resin in the resin portion 50 may be the identical component to the resin contained in the bonding portion 40. The main resin may be the resin that has the largest total weight among the resins contained in the resin portion 50, or may be the resin that has the largest total volume. Such a bonding portion 40 and a resin portion 50 can be produced by using, as an example, epoxy flux-containing solder, which will be described below.

The resin portion 50 may be provided between the source electrode 220 and the drain electrode 230. By providing the resin portion 50 between electrodes, the insulation performance between electrodes can be improved. In the cross section, the resin portion 50 may be provided throughout the entire region surrounded by the source electrode 220 and the drain electrode 230, and the first main surface 261 of the power device 200 and the surface 825 of the circuit board 810. That is, the resin portion 50 may be filled in the region. The resin portion 50 may be similarly provided between the source electrode 220 and the gate electrode 240, or between the drain electrode 230 and the gate electrode 240. The same may apply to the sub-source electrode 250.

The distance between the source electrode 220 and the drain electrode 230 may be less than 3.5 mm. As one example, when air fills the space between the source electrode 220 and the drain electrode 230, approximately 3.5 mm is necessary to ensure the isolation of 1.2 kV. The resin portion 50 may have greater isolation strength than air. In this manner, even if the distance is less than 3.5 mm, the isolation of 1.2 kV can be ensured. The distance may be less than 3.0 mm, or less than 2.5 mm, or less than 2.0 mm, or less than 1.5 mm, or less than 1.0 mm. The distance may be greater than 0.1 mm. The same may apply to the distance between the source electrode 220 and the gate electrode 240, or the distance between the drain electrode 230 and the gate electrode 240. The same may also apply to the distance between the sub-source electrode 250 and another electrode.

The resin portion 50 may be provided in at least one location outside the source electrode 220 or outside the drain electrode 230. Outside refers to the end portion side of rather than the center the device 200. In the present example, the outside of the drain electrode 230 may refer to the location between the drain electrode 230 and the end portion of the device 200 in a direction perpendicular to the paper surface. In the present example, the resin portions 50 are provided in both locations outside the source electrode 220 and outside the drain electrode 230. In addition, the resin portion 50 may also be provided outside the gate electrode 240 or outside the sub-source electrode 250.

The resin portion 50 may cover at least a portion of the side surface of the device 200. In the present example, the resin portion 50 covers the entire side surface of the sealing portion 260 and a portion of the side surface of the mounting substrate 210. In this manner, a breakdown voltage of the end portion (edge) of the device 200 can be ensured, thereby a non-isolated TIM (Thermal Interface Material) described below can be used.

The resin portion 50 may not cover the second main surface 262 of the device 200. This can prevent the resin portion 50 from becoming a thermal resistance when dissipating heat from the device 200. The resin portion 50 may not cover at least a portion of the side surface of the device 200. In another example, the resin portion 50 may cover the entire side surface of the device 200.

The resin portion 50 may be provided between the plurality of devices 200. Spaces between the plurality of devices 200 may refer to spaces between electrodes or between side surfaces of the plurality of devices 200.

The cooler 60 is arranged on a side opposite to the circuit board 810 with respect to the device 200. In the present example, the device 200-1 and the device 200-2 are placed on the cooler 60. For example, the cooler 60 may be a heat spreader, heat sink, or heat exchanger for liquid cooling.

The cooler 60 and each device 200 may be bonded by the sintering portion 70. The sintering portion 70 is an example of a TIM. The sinter material that configures the sintering portion 70 may be conductive. The sinter material may be silver. In the present example, the second main surface 262 of the device 200 is isolated, so a non-isolated TIM can be used. For example, the thermal conductivity of silver sinter material is approximately 200 times greater than that of heat dissipation grease. Therefore, in the present example, the semiconductor device 800 can greatly improve heat dissipation. The thickness of the sintering portion 70 may be 5 mm or less, or 1 mm or less, and may be 0.1 mm or more. The sintering portion 70 may protrude outward from the region between the device 200 and the cooler 60. Since the sintering portion 70 protrudes from between the device 200 and the cooler 60, it may be determined that the cooler 60 and the device 200 are sintered by the sintering portion 70. In addition, it may be determined that a sintering portion 70 is provided by analyzing the composition of the protruding portion described above or the material between the device 200 and the cooler 60.

The sintering portion 70 may not contact the resin portion 50. This can prevent the resin portion 50 from entering between the sintering portion 70 and the device 200 and becoming a thermal resistance. Note that the sintering portion 70 may contact the resin portion 50. Also in this case, the resin portion 50 is preferably not provided between the sintering portion 70 and the device 200. Similarly, the resin portion 50 is preferably not provided between the sintering portion 70 and the cooler 60. The resin portion 50 may not contact the cooler 60.

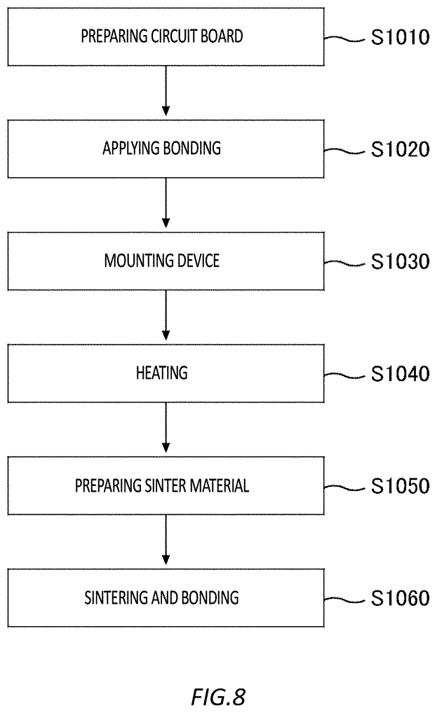

FIG. 8 is a flowchart showing one example of a manufacturing method of the semiconductor device 800. In the present example, the manufacturing method may include preparing a circuit board S1010, applying a bonding material S1020, mounting a device S1030, heating S1040, preparing a sinter material S1050, and sintering and bonding S1060.

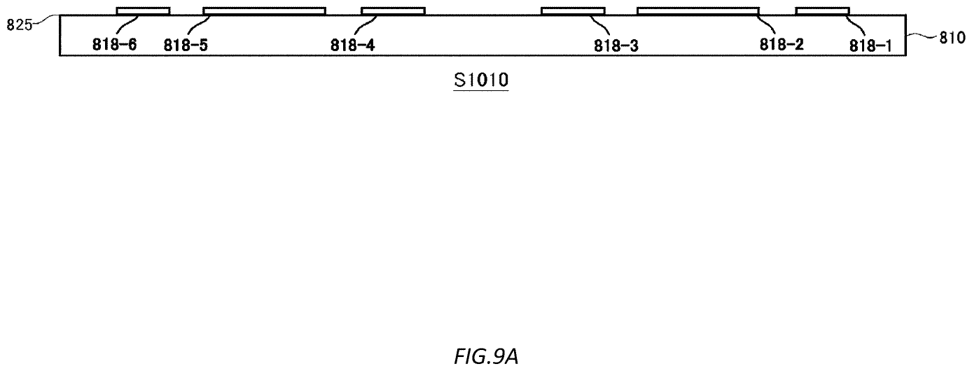

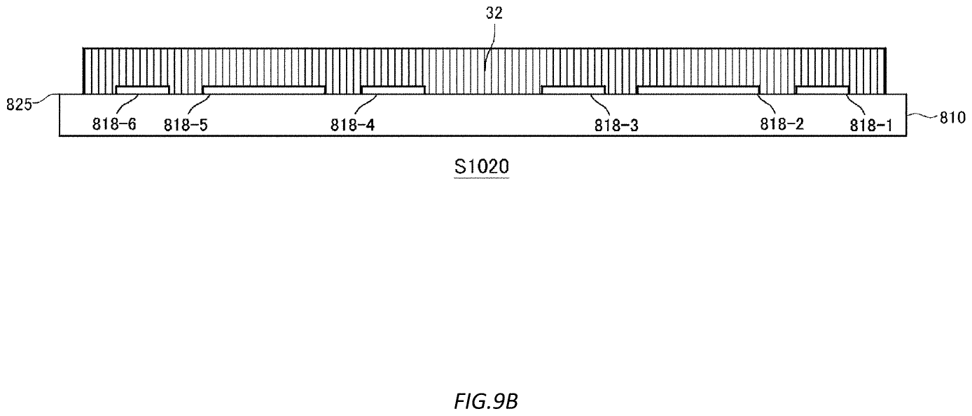

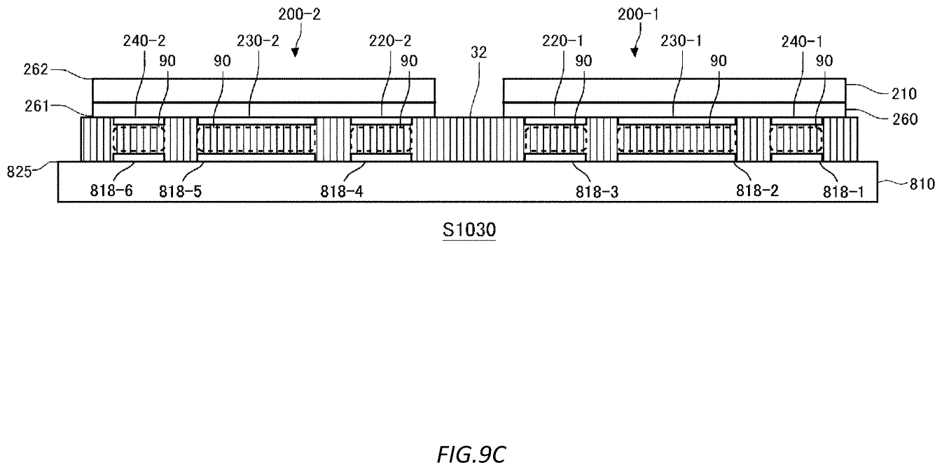

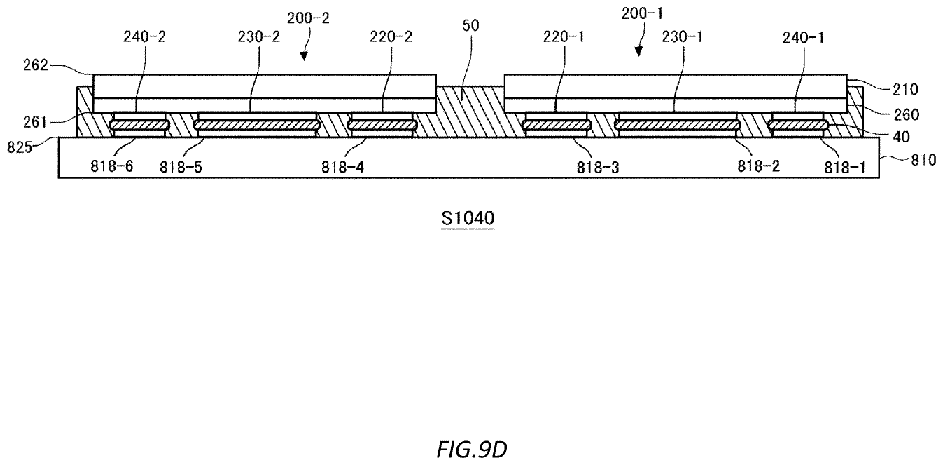

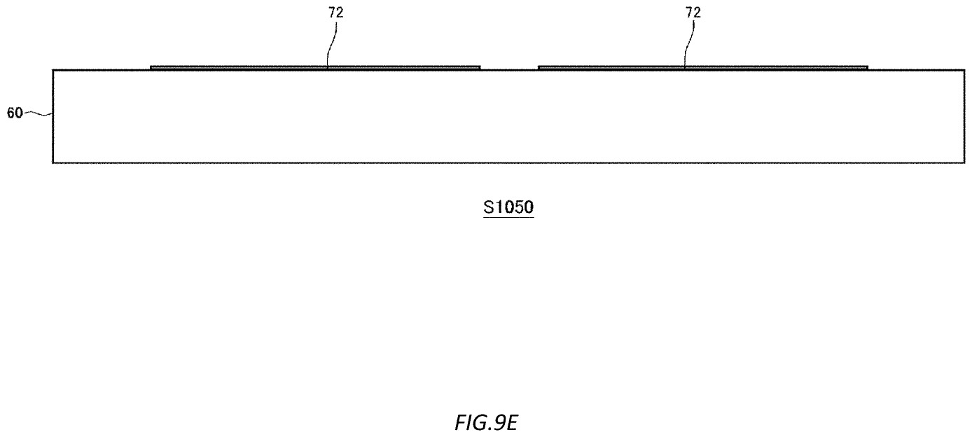

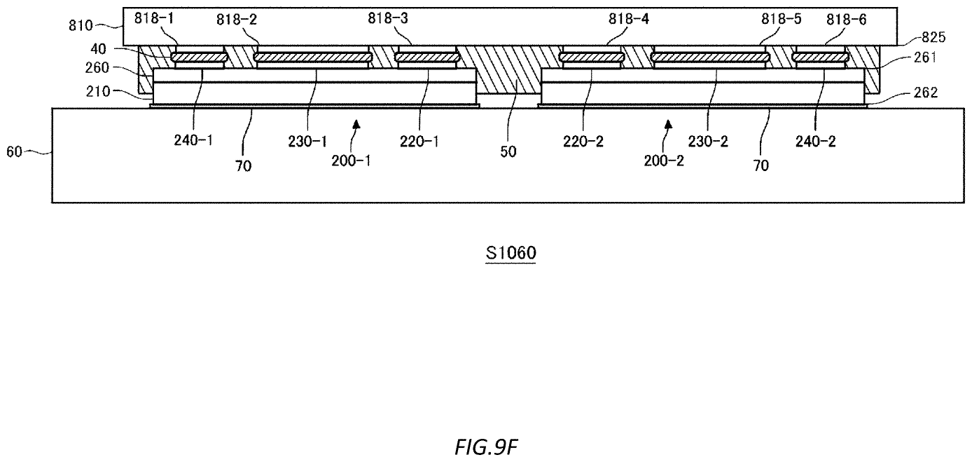

FIG. 9A illustrates preparing a circuit board S1010. In preparing the circuit board S1010, a circuit board 810 described in FIG. 7 is prepared. Note that in the description from this step to heating S1040, FIG. 9A illustrates the semiconductor device 800 with its top and bottom reversed with respect to FIG. 7.

FIG. 9B illustrates applying a bonding material S1020. In applying the bonding material S1020, a bonding material 32 is applied to the surface 825 of the circuit board 810. The bonding material 32 may be applied to cover the wirings 818-1 to 818-6. In FIG. 9B, the bonding material 32 is hatched.

The bonding material 32 may contain solder. In addition, the bonding material 32 may contain resin. That is, the bonding material 32 may be in a state where the solder and the resin are mixed. In the bonding material 32, the resin may have solder powder distributed therein. The solder may contain tin and may also contain lead. The solder may be, as an example, SAC305 solder, or eutectic solder, or high-temperature solder. The bonding material 32 may be flux-containing solder. Epoxy flux may be used as the flux. The volume ratio of the resin to the solder in the bonding material 32 is, as an example, 7:3 or 6:4. The volume ratio may be changed as appropriate according to the electrode area, electrode spacing, or the like of the device 200.

FIG. 9C illustrates mounting a device S1030. In mounting the device S1030, the device 200 is mounted to contact the bonding material 32. The surface contacting the bonding material 32 of the device 200 is a first main surface 261, and each electrode of the device 200 may be covered by the bonding material 32.

Each electrode and the wiring 818-1 to 818-6 of the device 200 may be arranged to overlap in a direction perpendicular to the first main surface 261. The region between a set of the source electrode 220 and the drain electrode 230, and the wirings 818-1 to 818-6 is referred to as a bonding area 90. The bonding area 90 may be filled by the bonding material 32. In addition, the region between another electrode such as the gate electrode 240 and the wirings 818-1 to 818-6 may be referred to as the bonding area 90.

In steps from preparing the circuit board S1010 to mounting the device S1030, the bonding material 32 is arranged between the device 200 and the circuit board 810. Note that in the present example, the manufacturing method is an example, for example, the bonding material 32 may be applied to the first main surface 261 of the device 200, and the circuit board 810 may be mounted thereon.

FIG. 9D illustrates the heating S1040. In the heating S1040, the bonding material 32 is heated. The solder contained in the bonding material 32 (for example, solder powder) aggregates in a region between each electrode of metal material and the wirings 818-1 to 818-6 by heating. In this manner, a portion of the resin contained in the bonding material 32 between each electrode and the wirings 818-1 to 818-6 is pushed outward from the bonding area 90 and forms the bonding portion 40. The bonding portion 40 bonds a set of the source electrode 220 and the drain electrode 230, and the wirings 818-1 to 818-6. In FIG. 9D, the bonding portion 40 is shown with fine hatching. Formation of the bonding portion 40 in the heating S1040 is described below.

In the heating S1040, a resin portion 50 is formed in a region other than the bonding area 90 between the device 200 and the circuit board 810. The resin portion 50 contains the same resin as the resin of the bonding material 32. The resin portion 50 may contain a resin pushed from the bonding area 90. No solder remaining from the bonding material 32 is present in the resin portion 50. The insulation performance, as described above, is improved by forming the resin portion 50. In particular, when device 200 is miniaturized and the distance between electrodes becomes smaller, it is desirable to form a resin portion 50 between electrodes to improve insulation performance. However, due to the small distance between electrodes, it becomes difficult to form the resin portion 50 after bonding device 200 to the circuit board 810. In the manufacturing method of the present example, the resin portion 50 can be formed between electrodes even if the distance between electrodes is small. In addition, since the bonding of the device 200 to the circuit board 810 and the formation of the resin portion 50 can be performed simultaneously, it is possible to suppress and increase in the number of processes. The resin portion 50 may not contain solder. In FIG. 9D, the resin portion 50 is shown with rough hatching.

When the heating S1040 is completed, the resin portion 50 may be provided between electrodes of the device 200 as described in FIG. 7, and may be provided outside the electrodes. This can improve the insulation performance. In addition, the resin portion 50 may cover at least a portion of the side surface of the device 200. This can make it possible to use a non-isolated TIM because, as described above, the breakdown voltage of the end portions (edges) of the device 200 can be ensured.

The resin portion 50 may not cover the second main surface 262 of the device 200 (a surface on a side opposite to the circuit board 810). This can prevent the resin portion 50 from becoming a thermal resistance. The resin portion 50 may not cover the entire second main surface 262. The end portion on the second main surface 262 side of the resin portion 50 may be located on a side of the first main surface 261 rather than the second main surface 262. In addition, when there are a plurality of devices 200, the resin portion 50 may be provided on all devices 200, or may be provided between the plurality of devices 200.

FIG. 9E illustrates preparing the sinter material S1050. In preparing the sinter material S1050, the sinter material 72 is formed on the surface of the cooler 60. As described above, the sinter material 72 may be conductive, as an example, may be silver.

FIG. 9F illustrates sintering and bonding S1060. In the sintering and bonding S1060, the sinter material 72 is heated, and the second main surface 262 of the device 200 is sintered and bonded to the cooler 60 by applying pressure. In the sintering and bonding S1060, the sinter material 72 is sintered, and becomes the sintering portion 70 such as sintered silver.

In the manufacturing process, after forming the resin portion 50, the second main surface 262 of the device 200 may be sintered to the cooler 60. The misalignment of each electrode of the device 200 and the wirings 818-1 to 818-6 is less tolerable than the misalignment of the cooler 60 and the device 200. By bonding the electrodes and the wirings 818-1 to 818-6 first, it can be possible to reduce the misalignment between the electrodes and the wirings 818-1 to 818-6. However, in that case, the bonding between the circuit board 810 and the device 200 is necessary to be able to withstand the pressure during sintering. The pressure during sintering is approximately 20 MPa, as an example. Even when using unpressurized sinter material as the sinter material 72, a pressure of approximately 5 MPa is applied. In the embodiment, a resin portion 50 is formed between the device 200 and the circuit board 810, or between the plurality of devices 200, thereby improving the bonding strength between the device 200 and the circuit board 810 and enabling it to withstand the pressure during sintering. In addition, the pressure applied from a surface opposite to the surface 825 of the circuit board 810 is uniformly applied to the sinter material 72 through the bonding portion 40 and the resin portion 50.

When the plurality of devices 200 are present, the plurality of devices 200 may be bonded collectively to the circuit board 810. Collectively bonding may be, for example, heating to bond the circuit board 810 and the plurality of devices 200 while, for example, the plurality of devices 200 are in a state of contacting the circuit board 810 via the bonding material 32 prior to heating. The heating may be performed, for example, by placing the circuit board 810 and the plurality of devices 200 in a furnace and heating the entire assembly.

When the plurality of devices 200 are present, the plurality of devices 200 may be sintered collectively onto the cooler 60. Collectively sintering may be, for example, heating and applying pressure to sintering and bonding the circuit board 810 and the plurality of devices 200 while, for example, the plurality of devices 200 are in a state of contacting the cooler 60 via the sinter material 72 prior to sintering.

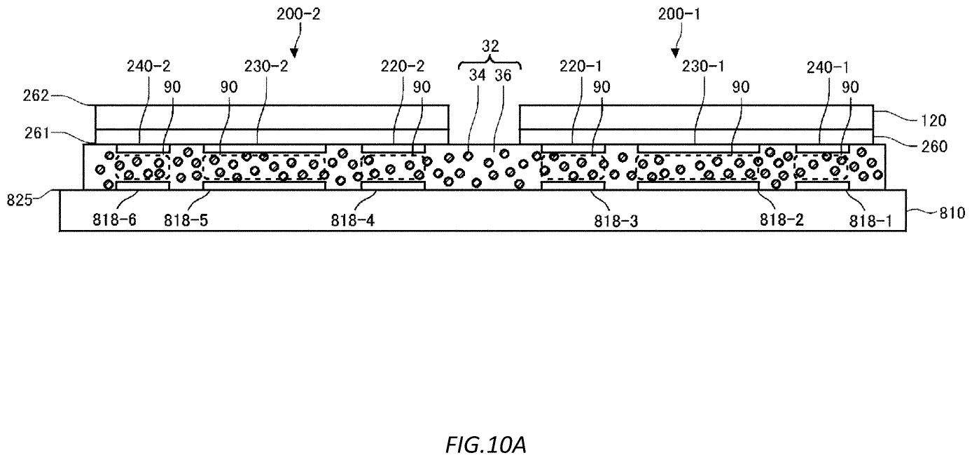

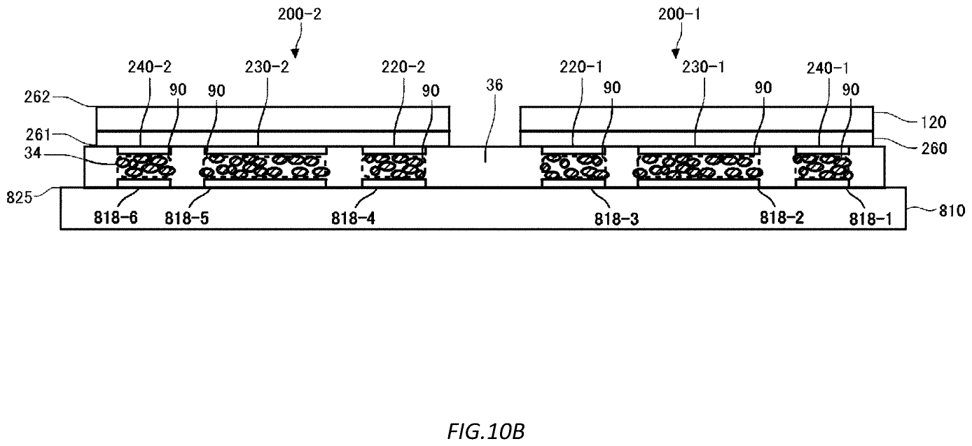

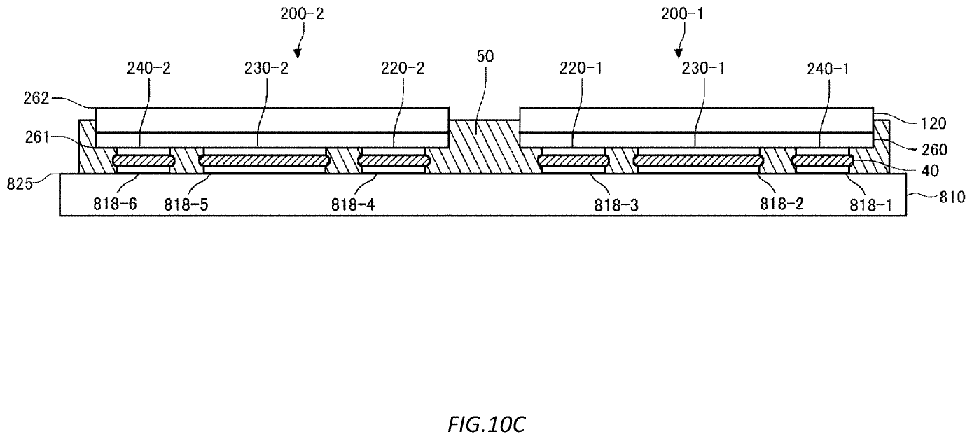

FIG. 10A to FIG. 10C illustrate the formation of the bonding portion 40 in the heating S1040. FIG. 10A shows a state of the bonding material 32 prior to heating. In FIG. 10A to FIG. 10C, the bonding material 32 is epoxy flux-containing solder. In the present example, the bonding material 32 contains the solder powder 34 and the resin 36. In this step, the solder powder 34 and the resin 36 are mixed together. In FIG. 10A, the solder powder 34 is hatched.

FIG. 10B shows a state of the bonding material 32 during heating. By heating the bonding material 32, the solder powder 34 is attracted by intermolecular forces or surface tension and self-organizes into agglomerates, forming a layer of solder (bonding portion) in the bonding area 90. In addition, a solder-repellent resist may be applied to portions of the circuit board 810 other than the wirings 818-1 to 818-6. In addition, since the sealing portion 260 of the device 200 is made of epoxy resin, so the solder does not wet. Therefore, the solder layer is formed between the electrodes and the wirings 818-1 to 818-6.

FIG. 10C shows a state of the bonding material 32 after heating. Furthermore, as shown in FIG. 10B, the solder aggregates and the bonding portion 40 is formed. In addition, the viscosity of the resin 36 decreases, and it is cured over time to form the resin portion 50. As the solder aggregates, a portion of the resin 36 that exists in the bonding area 90 is pushed outward from the bonding area 90 and becomes a portion of the resin portion 50. Note that another portion of the resin 36 that exists in the bonding area 90 is incorporated in the bonding portion 40. As a result, the resin portion 50 and the bonding portion 40 contain the resin 36 with the identical component.

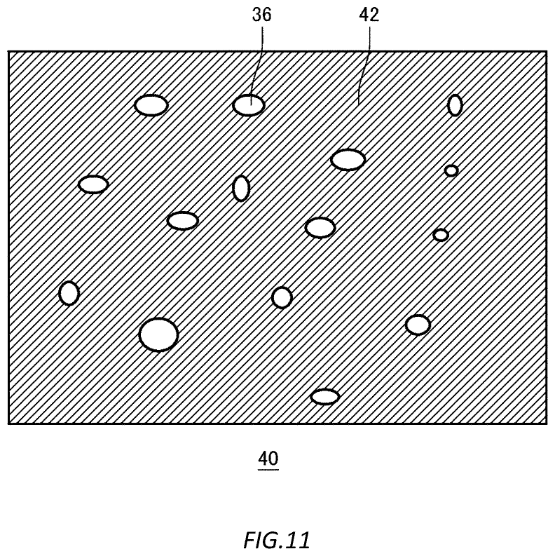

FIG. 11 is a schematic view showing an example inside the bonding portion 40. In the present example, the bonding portion 40 includes a solder layer 42 and the resin 36. Voids are formed in the solder layer 42 while forming the bonding portion 40. The resin 36 that exists in the bonding area 90 remains in the voids, so the bonding portion 40 contains the resin 36. The volume of the resin 36 in the bonding portion 40 may be 1% or less of the entire volume of the bonding portion 40, or 0.1% or less, and may be 0.01% or more.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that the embodiments to which such changes or improvements are made may be included in the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

What is claimed is:

1. A semiconductor device, comprising:
a circuit board with wiring;
a semiconductor device with a first main electrode and a second main electrode arranged on a first main surface;
a bonding portion which bonds the first main electrode and the second main electrode to the wiring; and
a resin portion provided in contact with the circuit board and the semiconductor device, in a region where the first main electrode and the second main electrode are not provided,
wherein the bonding portion contains a resin; and
the resin portion contains resin contains a resin of an identical component to the resin of the bonding portion.

2. The semiconductor device according to claim 1, wherein the resin portion is provided between the first main electrode and the second main electrode.

3. The semiconductor device according to claim 2, wherein a distance between the first main electrode and the second main electrode is less than 3.5 mm.

4. The semiconductor device according to claim 2, wherein the resin portion is provided in at least one of a location outside the first main electrode or a location outside the second main electrode.

5. The semiconductor device according to claim 1, wherein the resin portion covers at least a portion of a side surface of the semiconductor device.

6. The semiconductor device according to claim 5, comprising
a plurality of semiconductor devices, each of which is the semiconductor device,
wherein the resin portion is provided between the plurality of semiconductor devices.

7. The semiconductor device according to claim 1, comprising:
a cooler arranged on a side opposite to the circuit board with respect to the semiconductor device; and
a sintering portion that bonds the cooler and the semiconductor device.

8. The semiconductor device according to claim 7, wherein the sintering portion is not in contact with the resin portion.

9. A manufacturing method of a semiconductor device, comprising
arranging a bonding material containing resin between a semiconductor device with a first main electrode and a second main electrode arranged on a first main surface and a circuit board with a wiring; and
pushing a portion of the resin outside a bonding area that is a region between the first main electrode and the second main electrode and the wiring, to form a bonding portion that bonds the first main electrode and the second main electrode to the wiring.

10. The manufacturing method of the semiconductor device according to claim 9, wherein:
the bonding material contains solder; and
the solder is aggregated by heating the bonding material to push the resin.

11. The manufacturing method of the semiconductor device according to claim 10, wherein a resin portion is formed by heating the bonding material, containing a resin identical to the resin in a region other than the bonding area between the semiconductor device and the circuit board.

12. The manufacturing method of the semiconductor device according to claim 11, wherein the resin portion covers at least a portion of a side surface of the semiconductor device.

13. The manufacturing method of the semiconductor device according to claim 12, wherein the resin portion does not cover a surface opposite to the circuit board of the semiconductor device.

14. The manufacturing method of the semiconductor device according to claim 11, wherein a surface on a side opposite to the circuit board of the semiconductor device is sintered to a cooler after forming the resin portion.

15. The manufacturing method of the semiconductor device according to claim 14, wherein
a plurality of semiconductor devices, each of which being the semiconductor device, are collectively bonded to the circuit board; and
the plurality of semiconductor devices are collectively sintered to the cooler.

16. The semiconductor device according to claim 2, comprising:
a cooler arranged on a side opposite to the circuit board with respect to the semiconductor device; and
a sintering portion that bonds the cooler and the semiconductor device.

17. The semiconductor device according to claim 3, comprising:
a cooler arranged on a side opposite to the circuit board with respect to the semiconductor device; and
a sintering portion that bonds the cooler and the semiconductor device.

18. The semiconductor device according to claim 4, comprising:
a cooler arranged on a side opposite to the circuit board with respect to the semiconductor device; and
a sintering portion that bonds the cooler and the semiconductor device.

19. The semiconductor device according to claim 5, comprising:
a cooler arranged on a side opposite to the circuit board with respect to the semiconductor device; and
a sintering portion that bonds the cooler and the semiconductor device.

20. The semiconductor device according to claim 6, comprising:
a cooler arranged on a side opposite to the circuit board with respect to the semiconductor device; and
a sintering portion that bonds the cooler and the semiconductor device.
